(19) United States
(12) Patent Application Publication
(10) Pub. No.: US 2016/0196867 A1
(43) Pub. Date: Jul. 7, 2016

(54) STATIC MEMORY CELL WITH TFET STORAGE ELEMENTS

(71) Applicant: International Business Machines Corporation, Armonk, NY (US)

(72) Inventors: Leland Chang, New York, NY (US); Isaac Lauer, Yorktown Heights, NY (US); Amlan Majumdar, White Plains, NY (US); Jeffrey W. Sleight, Ridgefield, CT (US)

(21) Appl. No.: 14/589,075

(22) Filed: Jan. 5, 2015

(51) Int. Cl. G11C 11/419

(52) U.S. Cl. CPC G11C 11/419

(57) ABSTRACT

In some embodiments, an apparatus for storing data includes a state retention circuit configured to retain a first state when placed into the first state and a second state when placed into the second state, a write port operably connected to the state retention circuit and configured to receive a data input and place the state retention circuit into a written state corresponding to the data input, a read port operably connected to the state retention circuit and configured to drive a data output according to the written state. In one embodiment, the write port and the read port comprise CMOS transistors and no tunneling field effect transistors, and the state retention circuit comprises tunneling field effect transistors and no CMOS transistors. A corresponding system and computer readable medium are also disclosed herein.

### BACKGROUND OF THE INVENTION

The present invention relates generally to the field of memory devices, and more particularly to static memory devices.

The tunneling field-effect transistor (TFET) is a new type of metal-oxide-semiconductor field-effect transistor (MOSFET) proposed for low energy electronics. TFETs switch by modulating quantum tunneling through a barrier instead of an inversion layer as in traditional MOSFETs (e.g., CMOS transistors). Consequently, TFETs are not limited by the thermal Maxwell-Boltzmann tail of carriers, which limits the sub-threshold swing of MOSFETs to 60 mV/dec at room temperature.

The basic TFET structure is similar to a MOSFET except that the source and drain terminals of a TFET are doped of opposite type. A common TFET device structure consists of a P-I-N (p-type, intrinsic, n-type) junction, in which the electrostatic potential of the intrinsic region is controlled by a gate terminal. This basic concept has been applied to both silicon-based devices, as well as, new III-V materials to facilitate bandgap engineering. While TFETs remain promising, significant commercial usage has not yet occurred.

### SUMMARY

An apparatus, system, and method for storing data are disclosed herein. In one embodiment, the apparatus for storing data includes a state retention circuit configured to retain a first state when placed into the first state and a second state when placed into the second state, a write port operably connected to the state retention circuit and configured to receive a data input and place the state retention circuit into a written state corresponding to the data input, and a read port operably connected to the state retention circuit and configured to drive a data output according to the written state. In one embodiment, the write port and the read port comprise CMOS transistors and no tunneling field effect transistors, and the state retention circuit comprises tunneling field effect transistors and no CMOS transistors.

In some embodiments, the state retention circuit comprises a first inverter configured to receive a first input and provide a first output that is inverted from the first input, and a second inverter configured to receive a second input and provide a second output that is inverted from the second input, and wherein the first output is connected to the second input and the second output is connected to the first input. In certain embodiments, the write port is a pair of complementary pass transistors connected to a write word line and write bit lines. In some embodiments, the read port comprises a read transistor connected to the state retention circuit and a stacked transistor connected to a read word line and a read bit line.

In some embodiments, the system for storing data includes a memory device that includes the above described apparatus and at least one processing circuit configured to access the memory device. In certain embodiments, the method for storing data includes providing a memory device that includes the above described apparatus and storing data in the memory device. The method may also include retrieving data stored in the memory device and processing data retrieved from the memory device.

### BRIEF DESCRIPTION OF THE DRAWINGS

FIG. 1 is a graph that compares the current-voltage characteristics of a TFET with a CMOS transistor;

FIG. 2 is a schematic block diagram depicting one embodiment of a memory device in accordance with the present invention;

FIG. 3 is a schematic diagram depicting one embodiment of a memory cell in accordance with the present invention;

FIG. 4 is a schematic layout diagram depicting one embodiment of a memory cell layout in accordance with the present invention;

FIG. 5 is a schematic diagram depicting one embodiment of a memory array in accordance with the present invention;

FIG. 6 is a schematic layout diagram depicting one embodiment of a memory array layout in accordance with the present invention;

FIG. 7 is a block diagram depicting one embodiment of a processing system in accordance with the present invention; and

FIG. 8 is a flowchart depicting one embodiment of a processing method in accordance with the present invention.

### DETAILED DESCRIPTION

It should be noted that references throughout this specification to features, advantages, or similar language do not imply that all of the features and advantages that may be realized with the present invention should be, or are in, any single embodiment of the invention. Rather, language referring to the features and advantages is understood to mean that a specific feature, advantage, or characteristic described in connection with an embodiment is included in at least one embodiment of the present invention. Thus, discussions of the features, advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

These features and advantages will become more fully apparent from the following description and appended claims, or may be learned by the practice of the invention as set forth hereinafter.

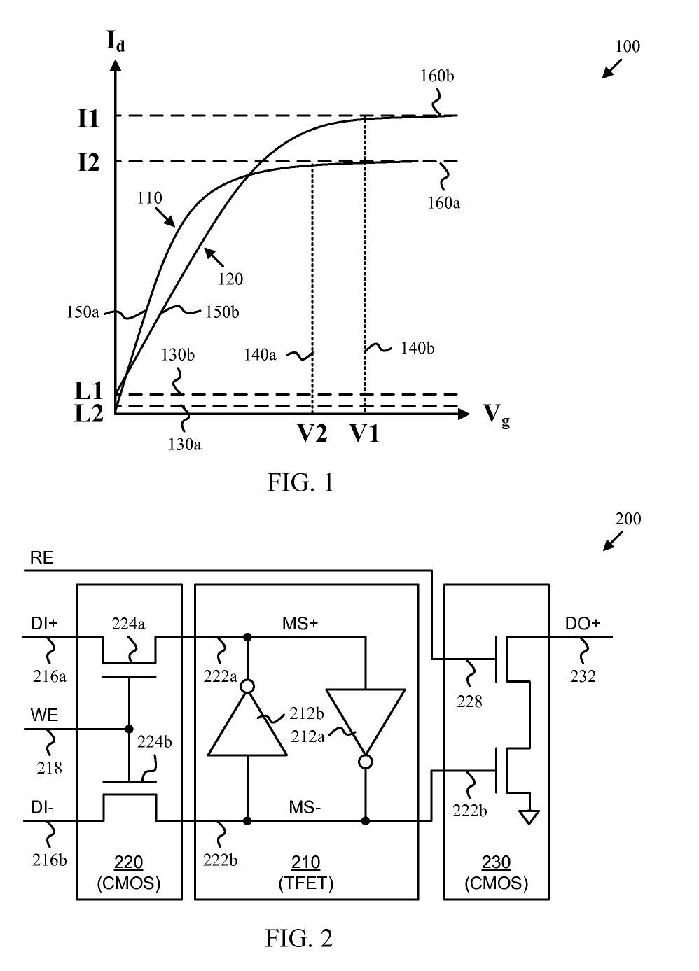

FIG. 1 is a graph 100 that compares a current response 110 of a tunneling field effect transistor (TFET) with a current response 120 of a CMOS transistor. As depicted, a TFET may have a leakage current 130a that is significantly lower than a leakage current 130b for a CMOS transistor and a lower operating voltage 140a than the operating voltage 140b of a CMOS transistor. A reduction in leakage current and operating voltage is significant for a variety of applications such as mobile applications where battery life is a persistent issue.

In addition to lower leakage current and operating voltage, a TFET may have a sharper turn-on slope 150a than a turn-on slope 150b for a typical CMOS transistor. For example, the turn-on slope 150b for a CMOS transistor may be inherently limited to 1 decade per 60 mV. In contrast, the turn-on slope 150a of a TFET is not inherently limited to 1 decade per 60 mV. As is understood by those skilled in the art, a sharper turn-on response can potentially result in faster transistor switching speeds and increased circuit performance. Despite the promise of TFETs, however, their use in commercial integrated circuits has not yet occurred due, not only to process integration challenges, but also because the drive current 160a of a TFET is typically significantly lower than the drive current 160b of a CMOS transistor.

At least some of the embodiments disclosed herein use TFET transistors and CMOS transistors in a manner that recognizes and leverages the strengths of each while avoiding their weaknesses. Specifically, TFETs are used within the core of a memory cell to retain state information with low leakage power while CMOS transistors are used to provide fast read and write access to the core of the memory cell.

For example, FIG. 2 is a schematic block diagram depicting one embodiment of a memory device 200 in accordance with the present invention. As depicted, the memory device 200 includes a state retention circuit 210, a write port 220, and a read port 230. In the depicted embodiment, the state retention circuit 210 comprises TFETs while the write port 220 and the read port 230 comprise CMOS transistors. The memory device 200 may be used in a variety of applications such as memory applications (e.g., as static RAM cells) and state retention applications (e.g., as registers or latches). While specific circuit examples are shown within the state retention circuit 210, the write port 220, and the read port 230, a wide variety of embodiments that fit within the spirit and intent of the claims are possible.

The state retention circuit 210 retains a memory state. In the depicted embodiment, the state retention circuit 210 is a pair of cross-coupled inverters 212 (i.e., inverter 212a and inverter 212b) where the input of each inverter 212 is tied to the output of the other inverter. The use of TFETs for this state retention circuit reduces the leakage power consumed by this portion of the cell.

The write port 220 receives a data input 216 and provides a state input/output 222. In the depicted embodiment, the write port 220 is a complementary pass gate comprised of a pair of pass transistors 224 that receive complementary data inputs 216a and 216b along with a write enable input 218. When the write enable input 218 is asserted, the pass transistors 224 (i.e., 224a and 224b) pass the complementary data inputs 216a and 216b to provide the complementary state inputs/outputs 222a and 222b.

One skilled in the art will appreciate that the complementary state inputs/outputs 222a and 222b must be driven with sufficient current to flip the state of the state retention circuit 210 when required. However, the use of TFETs with low drive current in the state retention circuit may significantly reduce the current required to set the state of the state retention circuit 210 and/or lower the time required to set the state of the state retention circuit 210.

The read port 230 receives the state input/output 222 (e.g., the state input/output 222a or the state input/output 222b) and provides a data output 232. In the depicted embodiment, the read port 230 receives the state input/output 222 along with a read enable input 228 and drives the data output 232 according to the state input/output 222 when the read enable input 228 is asserted. The use of CMOS transistors in the read port 230 eliminates the need for the state retention circuit 210 to provide a high output current and enables the use of TFETs in the state retention circuit 210.

As depicted, the read port 230 may be implemented with a pair of stacked transistors (i.e., a read stack) that are tied to an external pull-up transistor via the data output 232. The read stack may pull the data output 232 to an un-asserted (e.g., low voltage) state when the read enable input 228 is asserted and the state input/output 222 is un-asserted (e.g., the complementary state input/output 222b is asserted). One skilled in the art will appreciate that a wide variety of circuit configurations are possible for the read port 230 as well as the write port 220.

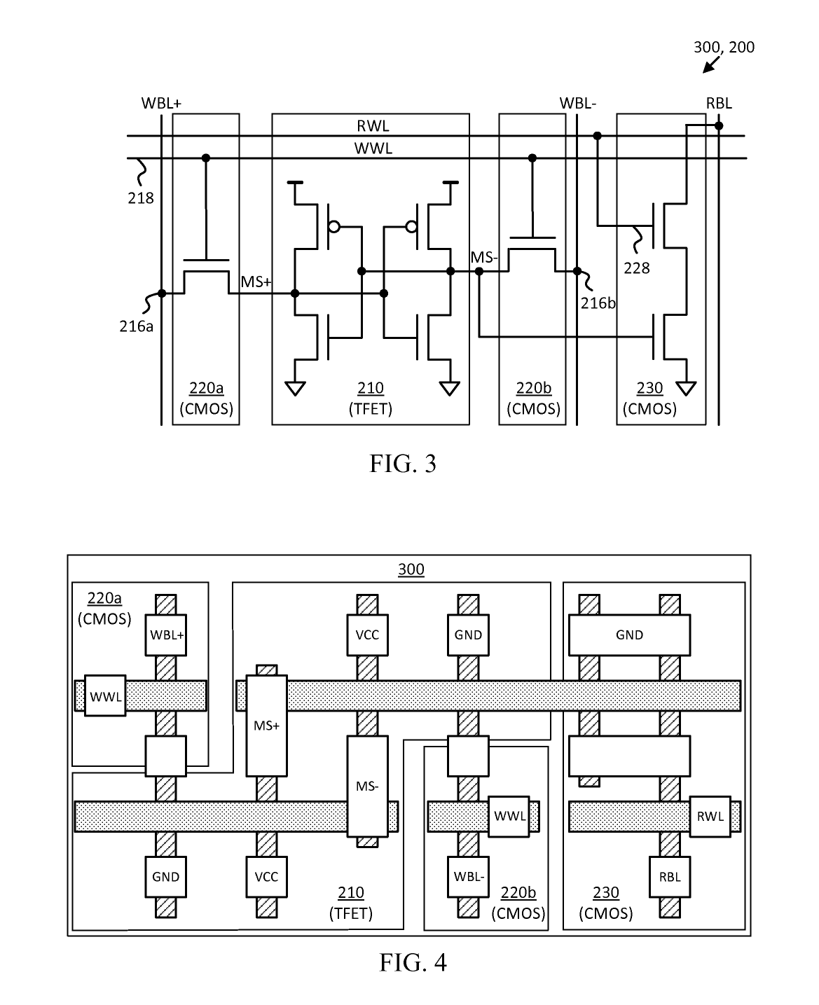

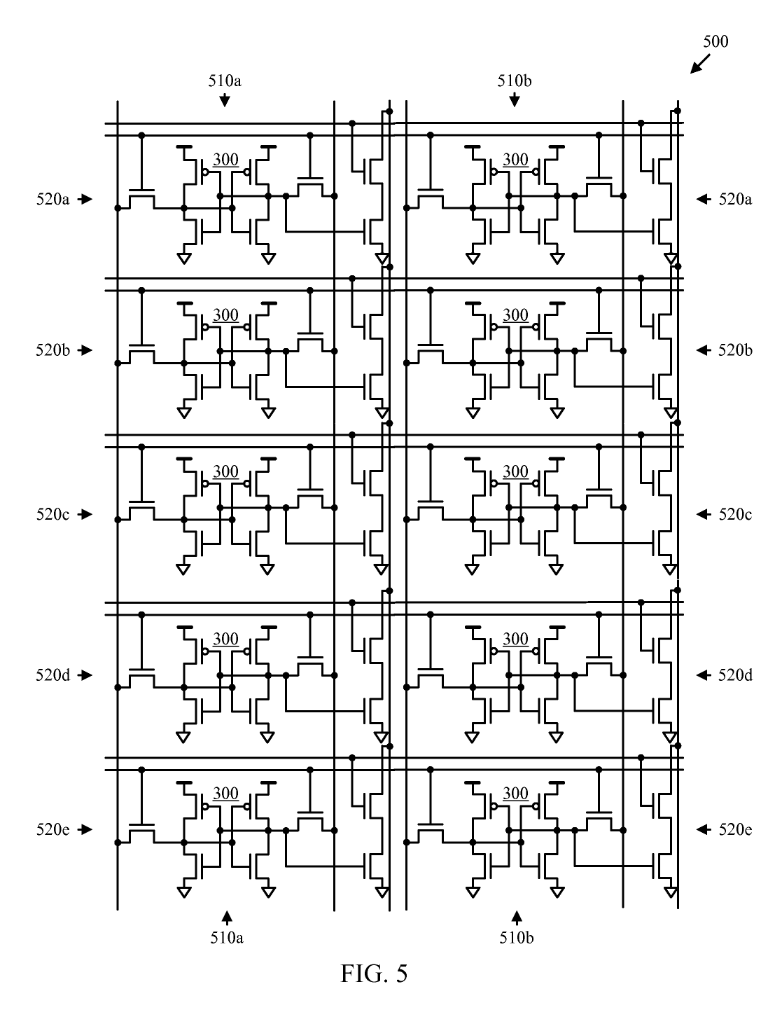

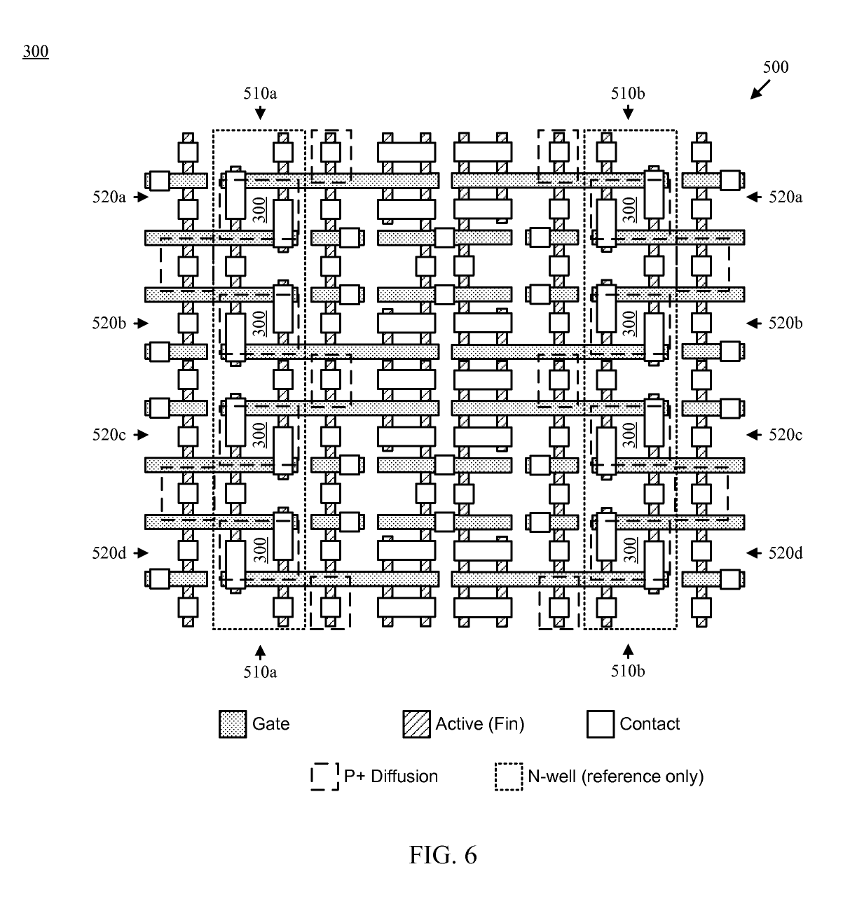

FIG. 3 is a schematic diagram, and FIG. 4 is one example of a corresponding layout diagram, depicting one embodiment of a memory cell 300 in accordance with the present invention. As depicted, the memory cell 300 includes the state retention circuit 210, the writing gate 220 (i.e., 220a and 220b), and the reading gate 230. The memory cell 300 may be configured to provide a high density array of memory devices as required by static RAM chips, or the like. In the depicted embodiments, the elements of the memory cell 300 are arranged to facilitate high density two dimensional arrays such as those shown in FIGS. 5 and 6.

Referring again to FIGS. 3 and 4, in some embodiments, the memory cell 300 is essentially the memory device 200, configured to be replicated and wired into a memory array. In the depicted embodiment, the complementary data inputs 216a and 216b are connected to complementary write bit lines (labeled WBL+ and WBL− in FIGS. 3 and 4). Also, the write enable input 218 and the read enable input 228, are wired to a write word line (WWL) and a read word line (RWL), respectively. Furthermore, the data output 232 is wired to a read bit line (RBL).

FIG. 5 is a schematic wiring diagram, and FIG. 6 is a layout diagram, depicting one embodiment of a memory array 500 in accordance with the present invention. As depicted, the memory array 500 is a 2D array of memory cells 300. FIG. 5 shows a 5 by 2 array (i.e., rows 520a-e and columns 510a-b) and FIG. 6 shows a 4 by 2 array (i.e., rows 520a-d and columns 510a-b). The layout in FIG. 6 shows an exemplary embodiment that can enable practical fabrication of the TFET storage devices in the memory cell. By utilizing a masked implant, the basic P-I-N structure in a TFET device can be created. One skilled in the art will appreciate that a variety of layout and wiring configurations could be used to implement an array of memory cells that are similar to the memory array 500.

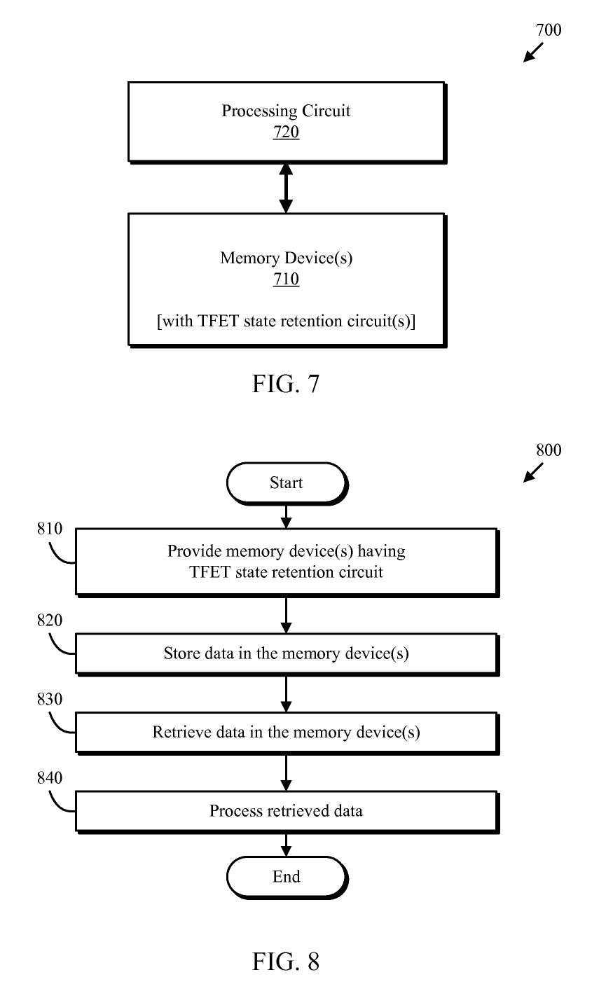

FIG. 7 is a block diagram depicting one embodiment of a processing system 700 in accordance with the present invention. As depicted, the processing system 700 includes a processing circuit 720 and one or more memory devices 710. The processing system 700 provides improved data processing over conventional systems.

The memory devices 710 may be integrated circuits that include one or more memory devices 200, memory cells 300, or memory arrays 500 that leverage state retention circuits 210 made of TFETs with writing gates 220 and/or reading gates 230 made of CMOS FETs.

FIG. 8 is a flowchart depicting one embodiment of a processing method 800 in accordance with the present invention. As depicted, the processing method 800 includes providing (810) one or more memory devices 200, storing (820) data in the memory devices 200, retrieving (830) data in the memory devices 200, and processing (840) the retrieved data. By leveraging TFETs within the memory devices 200, the processing method 800 enables improved data processing over conventional methods.

It should be noted that the apparatuses disclosed herein may be integrated with additional circuitry within integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be noted that this description is not intended to limit the invention. On the contrary, the embodiments presented are intended to cover some of the alternatives, modifications, and equivalents, which are included in the spirit and scope of the invention as defined by the appended claims. Further, in the detailed description of the disclosed embodiments, numerous specific details are set forth in order to provide a comprehensive understanding of the claimed invention. However, one skilled in the art would understand that various embodiments may be practiced without such specific details.

Although the features and elements of the embodiments disclosed herein are described in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. An apparatus for storing data, the apparatus comprising:
a state retention circuit configured to retain a first state when placed into the first state and a second state when placed into the second state;
a write port operably connected to the state retention circuit and configured to receive a data input and place the state retention circuit into a written state corresponding to the data input;
a read port operably connected to the state retention circuit and configured to drive a data output according to the written state;
wherein the write port and the read port comprise CMOS transistors and no tunneling field effect transistors; and
wherein the state retention circuit comprises tunneling field effect transistors and no CMOS transistors.

2. The apparatus of claim 1, wherein the state retention circuit comprises a first inverter configured to receive a first input and provide a first output that is inverted from the first input, and a second inverter configured to receive a second input and provide a second output that is inverted from the second input, and wherein the first output is connected to the second input and the second output is connected to the first input.

3. The apparatus of claim 1, wherein the write port is further configured to receive a write word line input and place the state retention circuit into the written state corresponding to the data input when the write word line input is asserted.

4. The apparatus of claim 3, wherein the write port is a set of complementary pass gates comprising complementary inputs and complementary outputs.

5. The apparatus of claim 4, wherein the complementary pass gate comprises a pair of pass transistors.

6. The apparatus of claim 4, wherein a first inverter and a second inverter of the state retention circuit are connected to a first output and a second output, respectively, of the complementary outputs of the complementary pass gate.

7. The apparatus of claim 1, wherein the read port is distinct from, and electrically isolated from, the write port, and the read port is further configured to receive a read word line input and drive the data output according to the written state when the read word line input is asserted.

8. The apparatus of claim 7, wherein the read port comprises a read transistor connected to the state retention circuit and a read enable transistor connected to the read word line input.

9. A system for storing and processing data, the system comprising:
a memory device comprising a state retention circuit configured to retain a first state when placed into the first state and a second state when placed into the second state, a write port operably connected to the state retention circuit and configured to receive a data input and place the state retention circuit into a written state corresponding to the data input, a read port operably connected to the state retention circuit and configured to drive a data output according to the written state, wherein the write port and the read port comprise CMOS transistors and no tunneling field effect transistors, and wherein the state retention circuit comprises tunneling field effect transistors and no CMOS transistors; and
at least one processing circuit configured to access the memory device.

10. The system of claim 9, wherein the state retention circuit comprises a first inverter configured to receive a first input and provide a first output that is inverted from the first input and a second inverter configured to receive a second input and provide a second output that is inverted from the second input, and wherein the first output is connected to the second input and the second output is connected to the first input.

11. The system of claim 9, wherein the write port is further configured to receive a write word line input and place the state retention circuit into the written state corresponding to the data input when the write word line input is active.

12. The system of claim 11, wherein the write port is a set of complementary pass gates comprising complementary inputs and complementary outputs.

13. The system of claim 12, wherein the complementary pass gate comprises a pair of pass transistors.

14. The system of claim 12, wherein a first inverter and a second inverter of the state retention circuit are connected to a first output and a second output, respectively, of the complementary outputs of the complementary pass gate.

15. The system of claim 9, wherein the read port is distinct from, and electrically isolated from, the write port, and the read port is further configured to receive a read word line input and drive the data output according to the written state when the read word line input is asserted.

16. The system of claim 15, wherein the read port comprises a read transistor connected to the state retention circuit and a read enable transistor connected to the read word line input.

17. A method for storing data, the method comprising:
providing a memory device comprising a state retention circuit configured to retain a first state when placed into the first state and a second state when placed into the second state, a write port operably connected to the state retention circuit and configured to receive a data input and place the state retention circuit into a written state corresponding to the data input, a read port distinct from, and electrically isolated from, the write port, the read port operably connected to the state retention circuit and configured to drive a data output according to the written state, wherein the write port and the read port comprise CMOS transistors and no tunneling field effect transistors, and wherein the state retention circuit comprises tunneling field effect transistors and no CMOS transistors; and
storing data in the memory device.

18. The method of claim 17, further comprising retrieving data stored in the memory device.

19. The method of claim 18, further comprising processing data retrieved from the memory device.

20. The method of claim 17, wherein the state retention circuit comprises a first inverter configured to receive a first input and provide a first output that is inverted from the first input and a second inverter configured to receive a second input and provide a second output that is inverted from the second input, and wherein the first output is connected to the second input and the second output is connected to the first input.
